(19) United States
(12) Patent Application Publication
(10) Pub. No.: US 2024/0093995 A1
(43) Pub. Date: Mar. 21, 2024

(54) DUAL-MODE CONTROL CIRCUIT FOR MICROELECTROMECHANICAL SYSTEM GYROSCOPES

(71) Applicants: STMICROELECTRONICS S.r.l., Agrate Brianza (IT); POLITECNICO DI MILANO, Milano (IT)

(72) Inventors: Carlo VALZASINA, Gessate (IT); Giacomo LANGFELDER, Milano (IT); Marco BESTETTI, Gallarate (IT); Andrea Giovanni BONFANTI, Milano (IT)

(21) Appl. No.: 17/933,743

(22) Filed: Sep. 20, 2022

(51) Int. Cl. G01C 19/5712; H03F 3/45

(52) U.S. Cl. CPC G01C 19/5712; H03F 3/45475

(57) ABSTRACT

The present disclosure is directed to a dual-mode control circuit for a microelectromechanical system (MEMS) gyroscope. A control circuit is coupled to a Lissajous frequency modulated (LFM) gyroscope to control amplitude of oscillation of a mass along two directions. The amplitude of oscillation is controlled by an automatic gain control (AGC) loop which allows the same amplitude of oscillation in both directions. An AGC is implemented with a combination of proportional control (P-type) and integral control (I-type) paths that maintain the correct Lissajous pattern of the oscillation of the mass. The AGC may include a dual-mode stage which is able to switch between a P-type control path and an I-type control path based on the operation of the LFM gyroscope. A fast start-up phase may be controlled by the P-type control path while the I-type path is pre-charged to be ready to use in a steady state condition.

### BACKGROUND

### Technical Field

The present disclosure is directed to a control circuit for a microelectromechanical system (MEMS) device, such as a gyroscope.

### Description of the Related Art

In general, frequency modulated (FM) inertial sensors provide high-stability for the applications which need long-term accurate motion measurement. FM inertial sensors have advantages of a large linear full-scale range (FSR), quasi-digital output, and insensitivity to temperature drifts of electronic offsets and gains.

FM inertial sensors are highly desirable for microelectromechanical system (MEMS) gyroscope applications, where a mass of the MEMS oscillates with different frequencies and any external motion may be detected as a modulation of the oscillation frequencies of the mass. Typically, two oscillation frequencies (modes) are coupled to the mass along two transverse directions. In a normal condition both oscillation modes have the same amplitude of the oscillation. In this oscillatory condition, a split mode between the two oscillation modes results in a Lissajous pattern of the mass oscillatory motion. This type of the MEMS gyroscope is known as Lissajous frequency modulated (LFM) gyroscopes due to the Lissajous pattern of the mass oscillatory motion. Any external motion may appear as a split mode modulation between the two modes of the oscillatory motion. The MEMS may detect the external motion by monitoring the split mode.

In LFM gyroscopes, a small deviation between the amplitudes of the oscillations of the two oscillation modes results in a distortion in the Lissajous pattern and consequently interrupts the operation of the LFM gyroscopes. To minimize the deviation, an oscillator circuit includes a control system to control the mode and amplitude of the oscillation of the mass. In some embodiments, the control system may include an automatic gain control (AGC) that provides a constant amplitude for the oscillations to stabilize the gyroscope performance. The design of the AGC is important for maintaining a fast start-up and stable operation of the LFM gyroscope.

### BRIEF SUMMARY

The present disclosure is directed to a dual-mode control circuit for a microelectromechanical system (MEMS) device, such as a gyroscope. The control circuit is part of a Lissajous frequency modulated (LFM) gyroscope to control an average oscillation amplitude of a mass along two oscillation directions.

The LFM gyroscope includes a structure (e.g., the mass) that oscillates along first and second directions. An amplitude of the oscillation is the same along the first and second directions while a frequency of oscillation in the first direction has a small deviation from a frequency of oscillation in the second direction transverse to the first direction. This same amplitude of the oscillation and the frequency deviation results in a Lissajous pattern of the oscillatory motion of the structure.

The amplitude of the oscillation of the structure is controlled by an automatic gain control (AGC) loop that allows the same amplitude of oscillation in both the first and second directions. However, distortion of the oscillation amplitude may happen due to an amplitude modulation between the first and second directions at the frequency deviation. If the motion amplitude distortion is wrongly processed by the AGC (control loop), a distortion of the Lissajous pattern may destroy the operation of the LFM gyroscope. The distortion of the Lissajous pattern may affect stability of the gyroscope performance. For instance, the stability of the gyroscope performance may be determined as a ratio between the input deviation and output deviation such as scale-factor stability. Accordingly, controlling the motion amplitude at the frequency deviation is an important factor for stabilizing the operation of the LFM gyroscope that is related to implementation of the AGC.

An AGC loop in an LFM gyroscope may be implemented based on standard proportional control (P-type) and integral control (I-type) feedbacks. The standard proportional feedback implementation of the AGC may result in distortion of the Lissajous pattern due to an imperfect control at the frequency deviation. In some embodiments, an extended bandwidth solution is used based on a feedback compensator (zero-pole) to extend the control bandwidth to frequencies much greater than the frequency deviation, which may limit a sensing bandwidth of the gyroscope. In addition, using an integral control (I-type) implementation of AGC may generate a long start-up time that is not appropriate for the LFM gyroscope.

In various embodiments of the present disclosure, an AGC is implemented with a combination of P-type and I-type control paths that maintain the correct Lissajous pattern of the structure of the LFM gyroscope. Maintaining the correct Lissajous pattern of the structure of the LFM gyroscope refers to keeping the amplitude of the oscillation of the structure the same for both directions of the oscillation. The AGC includes a dual-mode stage that is configured to switch between a P-type control path and an I-type control path based on the operation of the LFM gyroscope.

In some embodiments, a fast start-up phase is controlled by the P-type control path. During the start-up phase, the I-type path is pre-charged to be ready to use in a steady state condition. Then the I-type path may be used instead of the P-type path, when an amplitude of the oscillation is close to a target amplitude of the oscillation. The pre-charging of the I-type path provides a sufficient voltage to keep the oscillation at a desired amplitude.

### BRIEF DESCRIPTION OF THE SEVERAL VIEWS OF THE DRAWINGS

In the drawings, identical reference numbers identify similar features or elements. The size and relative positions of features in the drawings are not necessarily drawn to scale.

FIG. 1 is a block diagram of the MEMS gyroscope according to an embodiment disclosed herein.

FIG. 2 is a topology of the oscillator system in FIG. 1 according to an embodiment disclosed herein.

FIG. 3 is a block diagram of the amplitude gain control (AGC) of FIG. 2 according to an embodiment disclosed herein.

FIG. 4A is an integral stage of the block diagram in FIG. 3 in a pre-charge phase according to an embodiment disclosed herein.

FIG. 4B is an integral stage of the block diagram in FIG. 3 in an integration phase according to an embodiment disclosed herein.

FIG. 5 is a gain stage of the block diagram in FIG. 3 according to an embodiment disclosed herein.

FIG. 6 is a low-pass filter of the block diagram in FIG. 3 according to an embodiment disclosed herein.

FIG. 7 is a difference amplifier of the block diagram in FIG. 3 according to an embodiment disclosed herein.

FIG. 8 is a selector of the block diagram in FIG. 3 according to an embodiment disclosed herein.

FIG. 9 is an output buffer of the block diagram in FIG. 3 according to an embodiment disclosed herein.

FIGS. 10A-10C are transient responses of the block diagram in FIG. 3 according to an embodiment disclosed herein.

FIG. 11 is a flowchart illustrating a process of the control system described in FIG. 3 according to an embodiment disclosed herein.

### DETAILED DESCRIPTION

FIG. 1 schematically shows a block diagram of a microelectromechanical system (MEMS) gyroscope 100. In various embodiments, the MEMS gyroscope 100 is a Lissajous frequency modulated (LFM) gyroscope. The LFM gyroscope provides high stability for detecting an angular rate (rotation) with high accuracy. The MEMS gyroscope 100 includes a mass 150. In one embodiment, the mass 150 is a square proof mass that is free to actuate along two directions. For the LFM gyroscope, each direction of the actuation corresponds to a mode of oscillation. Thus, the mass 150 is actuating in a first direction by a first mode (a first frequency) and in a second direction, which is transverse to the first direction, by a second mode (a second frequency). The actuating of the mass 150 may be applied by electrostatic forces. The electrostatic forces may be applied to decoupled external frames 152, 154, 156, and 158 at the four sides of the mass 150 via comb fingers. In some embodiments, the mass 150 has a different structure along the first direction rather than the second direction, which results in a deviation between the first and second frequencies, known as split mode (frequency deviation f_{Δ}).

An oscillation along the first direction is controlled by a first oscillator 200 and an oscillation along the second direction is controlled by a second oscillator 210. A topology of the first oscillator 200 may be the same as a topology of the second oscillator 210. Thus, the internal block diagram of one oscillator is described hereinafter. In some embodiments, the oscillators 200 and 210 may be fully differential oscillating circuits. The oscillator 200 has an input contact 202 from the mass 150 to sense the oscillatory motion of the mass 150 and an output contact 204 to drive the mass 150 for actuating at the first frequency.

The sensed frequency by each of the oscillators 200 and 210 is converted to a digital signal and processed by a digital conversion and processing stage 250. A frequency to digital demodulator may convert the sensed frequency from each of the oscillators 200 and 210 to the digital signal. Then the digital conversion and processing stage 250 may compare a difference between the sensed frequencies with the split mode of the LFM gyroscope to detect any deviation between the sensed frequencies and the split mode. The motion of the mass 150 modulates the frequencies of the oscillation and consequently the split mode. Thus, the split mode measurement provides a sensing output rate of the MEMS gyroscope 100. In one embodiment, the oscillators 200 and 210 are integrated in a same chip. In one embodiment, the digital conversion and processing stage 250 is an external integrated circuit (IC) electrically coupled to the oscillators. In one embodiment, the chip of the oscillators may include frequency to digital demodulators.

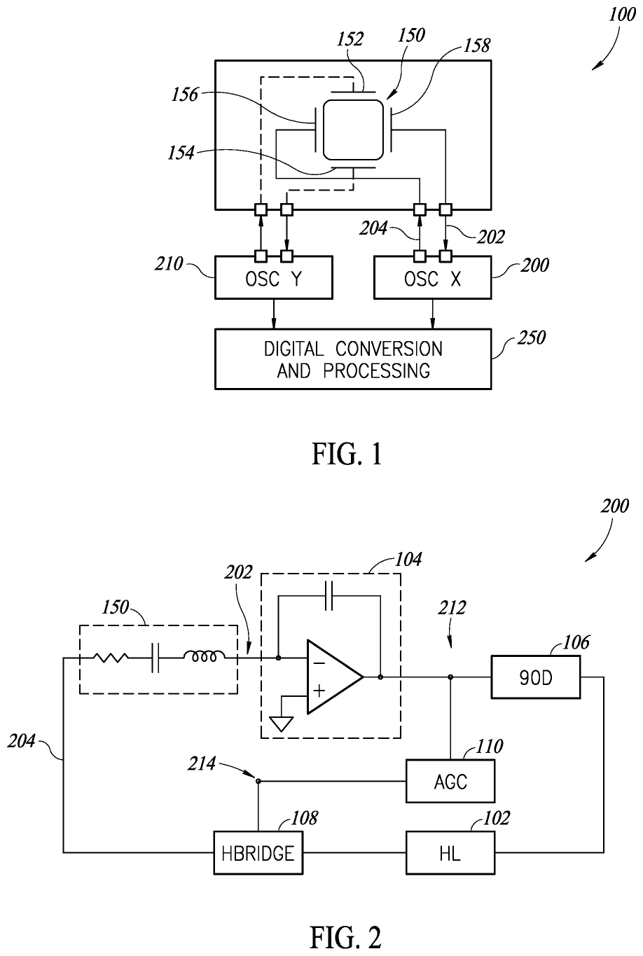

FIG. 2 illustrates more detail of the oscillator 200 in FIG. 1. As noted above, the topology of the first oscillator 200 may be same as the topology of the second oscillator 210.

In this embodiment, the mass 150 is modeled by an equivalent circuit that is electrically coupled to the oscillator 200 by the contacts 202 and 204 described in FIG. 1. The equivalent circuit of the mass 150 may be an RLC resonator having a resonance frequency corresponding to the oscillation frequency of the oscillator 200.

The mass 150 is electrically coupled to a charge amplifier 104. The oscillation of the mass 150 is detected by the charge amplifier 104 that is, for example, a capacitance-to-voltage (C2V) amplifier. The charge amplifier 104, as a front-end of the oscillator 200, detects oscillatory motion of the mass 150 as a capacitance variation and translates the capacitance variation into a voltage variation. In some embodiments, the charge amplifier 104 includes an op-amp with a feedback capacitor. A noise bandwidth of the charge amplifier 104 is typically about 100 times greater than the oscillation frequency and an output 212 of the charge amplifier 104 may drive a sinusoidal wave to the next stages. In addition, the charge amplifier can minimize white noise coupling to the oscillator 200.

The output 212 of the charge amplifier 104 is electrically coupled to a 90-degree phase shifter 106 and an automatic gain control (AGC) 110.

The 90-degree phase shifter 106 (90D) compensates a phase shift introduced by the charge amplifier 104 to the signal at output 212. In one embodiment, the 90-degree phase shifter 106 is implemented by an integrator-based shifter or a phase-locked loop (PLL). An output of the 90-degree phase shifter 106 is applied to a hard-limiter 102 (HL). In this fashion, the integrator may behave as an anti-aliasing filter in front of the hard-limiter 102 for noise folding minimization.

The hard-limiter 102 is electrically coupled to the 90-degree phase shifter 106. The hard-limiter 102 may implement a non-linear stage for oscillation build-up. In some embodiments, the hard-limiter 102 provides a square-wave for driving the mass 150, which may reduce power consumption of the oscillator 200. In one embodiment, the hard-limiter 102 is implemented by an open loop operational transconductance amplifier (OTA).

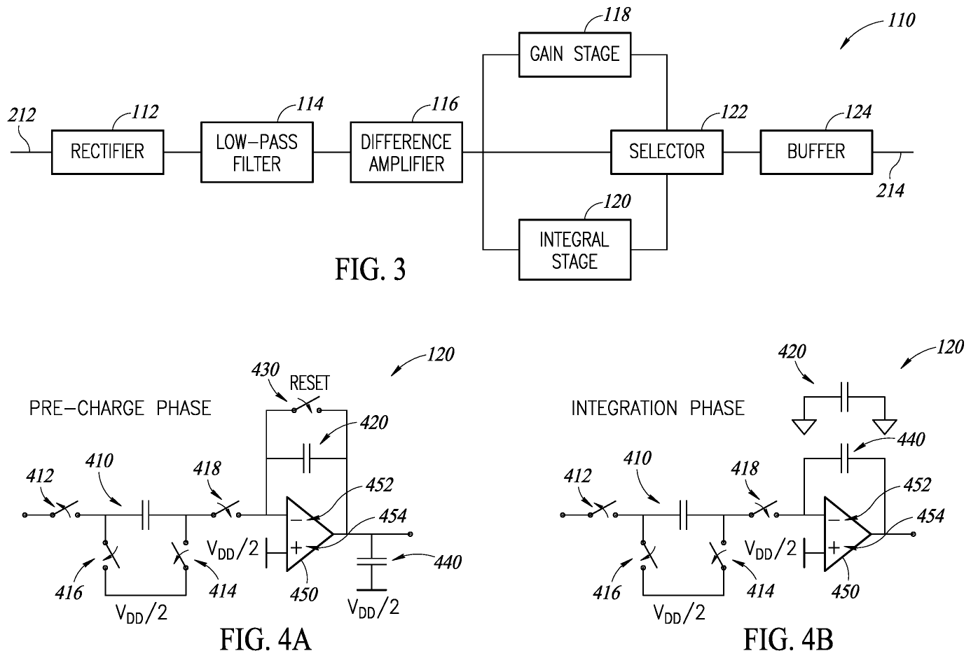

The square wave of the hard-limiter 102 is electrically coupled to an H-bridge 108, which delivers a drive actuation waveform to the mass 150 (the H-bridge 108 also known as a driver). The drive actuation waveform may apply to the mass as the electrostatic forces applied to decoupled external frames via comb fingers (e.g., 152, 154, 156, and 158 at the four sides of the mass 150 described in FIG. 1). The H-bridge 108 is supplied with a differential voltage from the AGC 110 at a contact 214, where the differential voltage of the AGC 110 adjusts the amplitude of oscillation to be the same in both directions of the oscillation. The AGC 110 is electrically coupled between the output 212 and the H-bridge 108. The AGC 110 is implemented by a negative feedback loop to extract oscillatory motion amplitude information (e.g., amplitude of the oscillation of the mass 150) from an envelope of the waveform from the charge amplifier 104 at the output 212. The AGC 110 compares the motion amplitude information to a motion amplitude reference to adjust the drive actuation waveform of the H-bridge 108 delivered to the mass 150. More detail of the AGC 110 and its operation is discussed with respect to FIGS. 3-10. The H-bridge 108 may be implemented by multiple switches (e.g., transistors arranged in H shape topology) to control both direction and speed of the actuation of the mass 150. The output of the H-bridge 108 is electrically coupled to the mass 150 by the contact 204.

FIG. 3 is a block diagram illustrating more detail of the AGC 110 described in FIG. 2. In this embodiment, the AGC 110 receives the waveform from the charge amplifier 104 at the output 212 by a rectifier 112. An output of the rectifier 112 is electrically coupled to a difference amplifier 116 after passing through a low-pass filter 114. An output of the difference amplifier 116 is electrically coupled to a gain stage 118 (gain control path) that provides a proportional control (P-type) path and an integral stage 120 (integral control path) that provides an integral control (I-type) path for the feedback loop of the oscillator 200 described in FIG. 2. A selector 122 compares the output of the difference amplifier 116 with an error threshold and based on the comparison selects one of the gain stage 118 or integral stage 120 to be electrically coupled to the H-bridge 108 by the contact 214 (as described in FIG. 2). The output of the selector 122 is electrically coupled to the contact 214 of the H-bridge 108 by an output buffer 124.

In one embodiment, the rectifier 112 is implemented by a butterfly-switch mixer or a full-brig rectifier, to rectify the waveform from the charge amplifier 104 at the output 212. Assuming the output of the charge amplifier 104 is a sinusoidal wave, the rectifier including a plurality of transistors or diodes, converts the sinusoidal wave to a substantially direct current (DC) voltage. This convention may result in some ripples on the DC output which is filtered by the low-pass filter 114 in the next stage.

The low-pass filter 114 removes frequencies above a threshold frequency from the rectified signal. As a result, oscillation ripples are removed from the rectified signal. In some embodiments, the combination of the rectifier 112 and the low-pass filter 114 may form an envelope detector that extracts the oscillatory motion information from the output signal of the charge amplifier 104. Thus, an output of the envelope detector, which is a DC analog signal, is electrically coupled to the difference amplifier 116. The difference amplifier 116 compares the DC signal from the envelope detector with a reference signal such as a reference voltage (V_{reff}) to generate an error signal. In one embodiment, the reference voltage (V_{reff}) is proportional to a target amplitude of the oscillation of the mass 150.

In various embodiments, the selector 122 is an automatic loop selector. In this fashion, the selector 122 compares the error signal from the difference amplifier 116 with an error threshold value proportional to the target amplitude of the oscillation of the mass 150.

Before the MEMS gyroscope 100 starts the operation, the mass 150 is fixed in a steady state. When the MEMS gyroscope starts the operation, the oscillator 200 detects the motion of the mass 150 which is close to zero at the starting point, which refers to a start-up phase. At the start-up phase, when the oscillation amplitude of the mass 150 is lower than the target amplitude of the oscillation, and consequently the error signal is greater than the error threshold, the selector 122 selects the gain stage 118 to be electrically coupled between the difference amplifier 116 and the output buffer 124 to form the P-type control path. The P-type control path benefits a fast build-up of the oscillation of the mass 150 at the start-up phase. When the detected amplitude of the oscillation becomes close enough to the target amplitude of the oscillation, which results in the error signal being less than the error threshold, then the selector 122 may select the integral stage 120 to be electrically coupled to the output buffer 124 to form the I-type control path.

In one embodiment, the integral stage 120 includes a switched-capacitor (SC) integrator circuit with an ideal infinite loop-gain at DC and a sub-Hz bandwidth. In this fashion, the I-type control path may be pre-charged during the start-up phase, to be ready to use in a steady state condition. The pre-charging of the I-type control path provides a sufficient voltage to keep the oscillation at the desired amplitude, when switching from the P-type control path to the I-type control path. Thus, the integral stage 120 has twofold operation modes, where a first operation mode corresponds to the start-up phase and a second operation mode corresponds to the steady state condition.

After selecting the I-type control path by the selector 122, the AGC 110 may continue using the I-type control path until the oscillator 200 is switched off. In some embodiments, a shock to the MEMS gyroscope 100 may cause the error signal to increase to a value greater than the error threshold. In this situation, the selector 122 selects the P-type control path for a fast recovery. Afterward, when the oscillation returns to a steady state condition, where the error signal becomes less than the error threshold, the selector 122 again selects the I-type control path for stabilizing the operation of the MEMS gyroscope 100.

Hence, the combination of the P-type and I-type control paths while the P-type control path operates during the fast start-up phase and the I-type control path is pre-charged during the fast start-up phase, benefits keeping the oscillatory motion of the mass 150 always within the correct Lissajous pattern for the LFM MEMS gyroscope 100.

FIG. 4A illustrates more detail of the integral stage 120 of the block diagram in FIG. 3 when operating in the pre-charge phase while the error signal is greater than the error threshold and the selector 122 selects the P-type control path for the start-up phase. In this embodiment, the integral stage 120 is a switched-capacitor (SC) integrator circuit including a plurality of capacitors and a plurality of switches electrically coupled to an operational amplifier (op-amp). In particular, the integral stage 120 includes an op-amp 450, an input capacitor 410 electrically coupled to an inverting input 452 of the op-amp 450, a fast feedback capacitor 420 electrically coupled between the inverting input 452 and an output of the op-amp 450, and a slow feedback capacitor 440 electrically coupled to the output of the op-amp 450. A reset switch 430 is electrically coupled in parallel to the fast feedback capacitor 420. In this fashion, the reset switch 430 is open in the pre-charge phase while it is closed in the integration phase (as described in FIG. 4B). Hence, the reset switch 430 may control the twofold operation modes of the integral stage 120.

In various embodiments, four switches 412, 414, 416, and 418 are electrically coupled to the input capacitor 410 to form an equivalent resistance by the switched-capacitor topology, where the equivalent resistance is proportional to a switching time and capacitance of the input capacitor 410. In some embodiments, a virtual ground (low logical level) of the integral stage 120 is electrically coupled to a common mode voltage that is half of a voltage supply VDD (VDD/2). In this fashion, a clocking system may control the switches 412, 414, 416, and 418 by a switching frequency. The switching may have a first state where the switches 412 and 414 are closed together while switches 416 and 418 are open. In the first state the input capacitor 410 is charged to an input voltage coupling to the integral state 120, which is equivalent to the output voltage of the difference amplifier 116 in FIG. 3. In a second state of the switching, the switches 412 and 414 are open together while switches 416 and 418 are closed. In the second state, the charged voltage from the input capacitor 410 is transferring to the output of the integral stage 120 through the fast feedback capacitor 420 (or the slow feedback capacitor 440 in the integration phase of FIG. 4B). In some embodiments, the switching frequency may be about 1 KHz. This type of switched-capacitor topology may produce a desired equivalent resistance by changing the switching time, while avoiding the use of a resistor benefits the integration space of the circuit as well as frequency response accuracy.

In some embodiments, the reset switch 430 may be controlled by a different clocking system than the clocking system that controls the switches 412, 414, 416, and 418. During the pre-charge phase, which the AGC 110 is operating with the P-type control path, the reset switch 430 is open and the slow feedback capacitor 440 is pre-charged to a proper value based on the transferred charge from the input capacitor 410. Once the AGC 110 switched to I-type control patch operation, the reset switch 430 turns into a closed state to bypass the fast feedback capacitor 420. In this fashion, a non-inverting input 454 of the op-amp 450 is electrically coupled to the common voltage VDD/2 that is the same as the virtual ground electrically coupled to the slow feedback capacitor 440. Typically, a voltage of an inverting input of an op-amp is about the same as a voltage of a non-inverting input. Thus, the voltage of the inverting input 452 is about the same as the common voltage VDD/2 of the non-inverting input 454. In this fashion, during the pre-charge phase, the slow feedback capacitor 440 is virtually in parallel with the fast feedback capacitor 420 and is pre-charged to a voltage the same as the voltage across the fast feedback capacitor 420.

FIG. 4B is the integral stage 120 in the integration phase when the reset switch 430 is closed (short) while the error signal becomes less than the error threshold, and the selector 122 selects the I-type control path for the steady state condition. In this fashion, the pre-charged slow feedback capacitor 440 is equivalent to the feedback capacitor of the integral stage 120, while the voltage on the inverting input 452 is about the same as the voltage VDD/2 electrically coupled to the slow feedback capacitor 440. Hence, the pre-charge voltage of the slow feedback capacitor 440 provides a fast starting up of the integral stage 120 while avoiding discontinuities in the loop operation. In particular, when switching from the P-type control path to the I-type control path, the output of the integral stage 120 should be reasonably matched with the voltage needed to keep the oscillation at the desired amplitude. In absence of the pre-charged value, a long transition time may be needed to reach the desired oscillation amplitude by the integral stage 120. The pre-charged phase of the integral stage 120 benefits the fast starting up by coupling the pre-charged slow feedback capacitor 440 to the output of the integral stage when the I-type control path is selected by the selector 122 in FIG. 3. In some embodiments, a ratio between the slow feedback capacitor 440 and the input capacitor 410 may be designed based on the desired split mode. For example, the slow feedback capacitor 440 may be about 100 times greater than the input capacitor 410 for a split mode about 100 Hz. In some embodiments, the slow feedback capacitor 440 may include a plurality of capacitors, where each of the plurality of capacitors equals to the input capacitor 410. In this fashion, the number of the plurality of the capacitors may be selected based on the desired split mode.

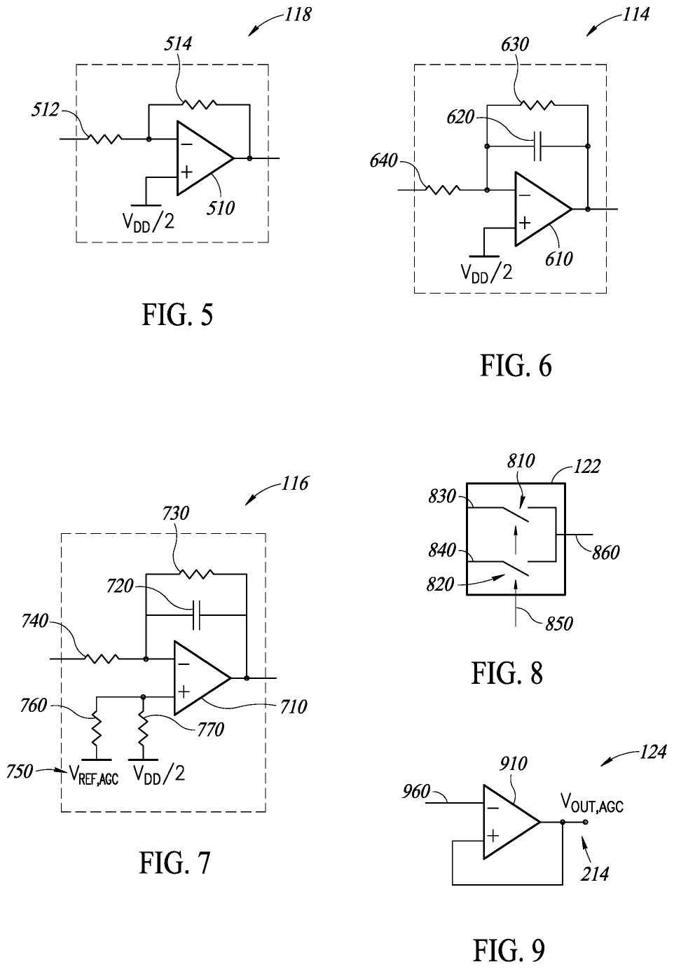

In some embodiments, the AGC 110 of FIG. 3 may be integrated in a CMOS process (e.g., a 0.13 μm CMOS process). In some embodiments, the voltage VDD may be about 3.6V. In various embodiments, each of the low-pass filter 114, difference amplifier 116, gain stage 118, selector 122, and output buffer 124 may be implemented by different circuit topologies. FIGS. 5-9 show some examples of the circuit topologies to implement the components of the block diagram of AGC 110 in FIG. 3.

FIG. 5 is an implementation of the gain stage 118 of the AGC 110 in FIG. 3. The gain stage 118 is a wide-bandwidth amplifier based on an op-amp 510. In this fashion, the gain stage 118 is an inverting op-amp including a resistor 512 electrically coupled to an inverting input of the op-amp 510 and a resistor 514 electrically coupled between the inverting input and an output of the op-amp 510. A gain of the inverting op-amp is proportional to a negative ratio of the resistor 514 and the resistor 512. Hence, during the start-up phase where the P-type control path is selected by the selector 122, the output of the difference amplifier 116 is electrically coupled to the input of the inverting op-amp. In this condition, the output of the inverting op-amp is a negatively amplified voltage by a gain proportional to the ratio of the resistor 514 and the resistor 512. This inverting op-amp topology has very fast response that benefits the fast start-up phase of the AGC 110.

FIG. 6 is an implementation of the low-pass filter 114 of the AGC 110 in FIG. 3. The low-pass filter 114 is an active filter based on an op-amp 610. In this fashion, the active filter includes an input resistor 640, a feedback resistor 630, and a feedback capacitor 620 that is electrically coupled in parallel with the feedback resistor 630. In some embodiments, the low-pass filter 114 may be an inverting amplifier filter, where the input resistor 640 is electrically coupled to the inverting input of the op-amp 610. In a low frequency region (lower than a cut off frequency of the filter) a reactance of the capacitor 620 is much larger than the resistor 630. Thus, the low frequency signals may be passed through the inverting amplifier by a gain proportional to the ratio of the resistors 630 and 640. In some embodiments, the resistor 630 may be the same as the resistor 640 to create a unit gain of the inverting amplifier. However, in a higher frequency range (higher than the cut off frequency) the reactance of capacitor 620 is decreased and the parallel combination of the capacitor 620 and the resistor 630 may filter the signals from the output of the low-pass filter 114. In various embodiments, the cut off frequency of the low-pass filter may be designed by the capacitor 620 and the resistor 630. The low-pass filter 114 reduces the oscillation ripple that is induced from the rectified oscillation amplitude from the rectifier 112. In some embodiments, the oscillation frequency of the oscillator 200 may be about 50 KHz while a split mode is about 100 Hz.

FIG. 7 is an implementation of the difference amplifier 116 of the AGC 110 in FIG. 3. The difference amplifier 116 includes an op-amp 710 with an RC feedback to an inverting input such as the RC circuit described in FIG. 6. An input signal from the low-pass filter 114 is electrically coupled to the inverting input of the op-amp 710 by a resistor 740. The inverting input is electrically coupled to the output of the op-amp 710 by a resistor 730 and a capacitor 720 in parallel with the resistor 730. A reference voltage (V_{refAGC}) 750 is electrically coupled to a non-inverting input of the op-amp 710 by a voltage divider circuit. The voltage divider circuit includes two resistors 760 and 770. In some embodiments, the resistors 730, 740, 760, and 770 may have about the same resistance value. The reference voltage 750 may be designed based on the target amplitude of the oscillation of the mass 150. In this fashion, when the input signal to the difference amplifier 116 is equal to the reference voltage 750, the amplitude of the detected oscillation is matched to the target amplitude of the oscillation. Hence, there is no difference between the input signal and the reference voltage 750 to be amplified. However, when the amplitude of the detected oscillation is different than the target amplitude of the oscillation, then the input signal has a difference with the reference voltage 750. In this condition, the difference amplifier detects the difference voltage between the inverting and non-inverting inputs of the op-amp 710 and consequently amplifies the difference voltage to be supplied to the H-bridge 108 of FIG. 2 for compensating the difference between the amplitude of the detected oscillation and the target amplitude of the oscillation.

FIG. 8 is an implementation of the selector 122 of the AGC 110 in FIG. 3. The selector 122 includes a comparator to compare the output signal from the difference amplifier 116 with an error threshold proportional to the target amplitude of the oscillation. In some embodiments, the error threshold is a voltage value that determines transition from a fast AGC mode (P-type control path) to a slow AGC mode (I-type control path). In various embodiments, the selector 122 includes a first switch 810 electrically coupled between an input 830 from the P-type control path and an output 860 of the selector 122, and a second switch 820 electrically coupled between an input 840 from the I-type control path and the output 860 of the selector 122. The output 860 is electrically coupled to the output buffer 124 in FIG. 3. In some embodiments, during the start-up phase, the signal error is greater than the error threshold and the P-type control path should be selected for a fast start-up of the oscillator 200 in FIG. 2. Thus, a control signal 850 may close the first switch 810 and open the second switch 820 to couple the P-type control path to the output 860. When the amplitude oscillation is close to the target amplitude of the oscillation, the error signal is reduced to a value equal or less than the error threshold. In this condition, the control signal 850 may convert the AGC operation mode from a fast start-up mode to a slow mode. Accordingly, the control signal 850 may open the first switch 810 and close the second switch 820 to couple the I-type control path to the output 860. In various embodiments, the comparator to generate the control signal 850 may be implemented by a Schmitt trigger circuit.

FIG. 9 is an implementation of the output buffer 124 of the AGC 110 in FIG. 3. The output buffer 124 is an op-amp follower circuit including an op-amp 910. This type of op-amp follower circuit has an output voltage same as the input voltage of the buffer 124, while providing a very high input impedance and very low output impedance. In this fashion, the output 860 from the selector 122 in FIG. 8 is electrically coupled to the non-inverting input 960 of the op-amp 910. An output of the op-amp 910 is electrically coupled to the contact 214 of the H-bridge 108 in FIG. 2. Hence, the AGC 110 may derive the H-bridge 108 with the differential voltage and enough current from the output buffer 124 independent from the input impedance of the op-amp 910.

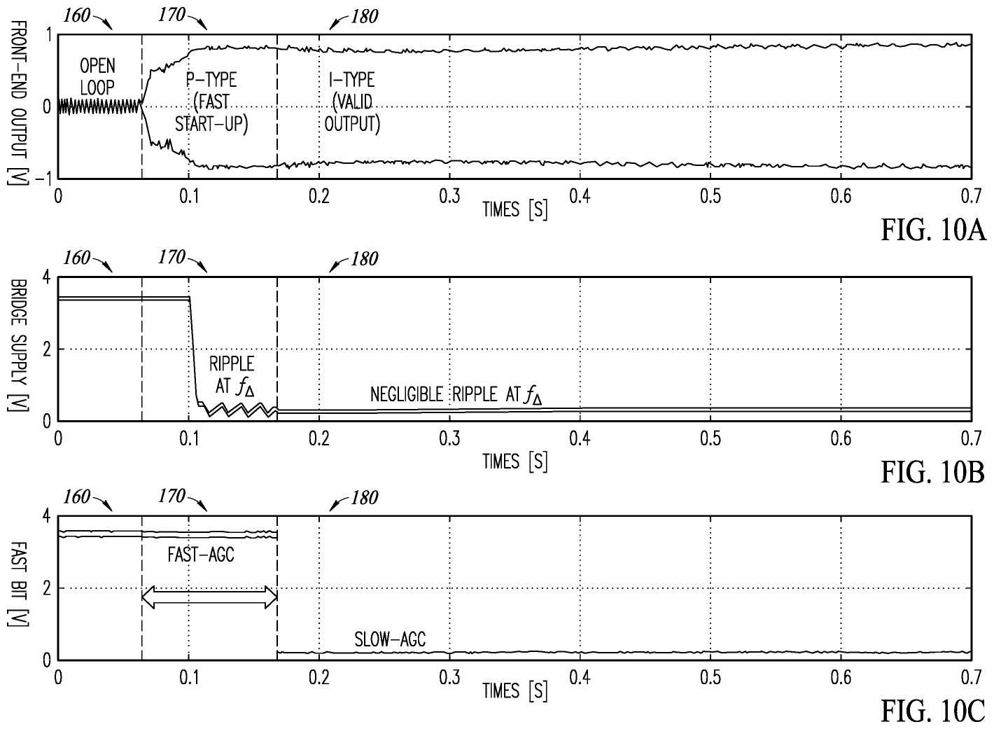

FIGS. 10A-10C are transient responses of the AGC 110 in FIG. 3. A horizontal axis of the FIGS. 10A-10C is in a time unit and a vertical axis of the FIGS. 10A-10C is in a voltage unit. The time of the transient responses is divided into three regions. A first region 160 depicts a period of time in which the MEMS gyroscope 100 is not in operation. A second region 170 depicts a period of time in which the MEMS gyroscope 100 starts working and the oscillator 200 is activated. A third region 180 depicts a period of time in which the amplitude of the oscillation is close to the target amplitude of the oscillation. The time and voltages in the horizontal and vertical axes may be normalized values and may be different in various embodiments. For instance, a period of time for the region 170 may be about 100 ms (milliseconds) in some embodiments.

FIG. 10A shows a transient voltage at the output 212 of the charge amplifier 104 in FIG. 2. In the first region 160, there is no oscillatory motion of the mass 150 in FIG. 2, and consequently the corresponding voltage level is about zero. In the second region 170 the MEMS gyroscope 100 starts working by oscillating the mass 150, then the corresponding voltage level is increased to reach to the target amplitude of the oscillation. The second region 170 corresponds to the start-up mode, where the AGC 110 operates by the P-type control path for a fast start-up. In the third region 180, the amplitude of the oscillation is close to the target amplitude of the oscillation, thus, the converted voltage level is about a constant value correspondence to the amplitude of the oscillation. The third region 180 corresponds to the slow mode, where the AGC 110 operates by the I-type control path for a long-time oscillation control.

FIG. 10B shows a transient voltage at the contact 214 of the AGC 110 in FIG. 2. In the first region 160, there is no oscillatory motion of the mass 150 in FIG. 2, and consequently the contact 214 of the AGC 110 is in high voltage level as a standby voltage to derive the oscillatory motion. In the second region 170 the MEMS gyroscope 100 starts working by oscillating the mass 150, then by increasing the amplitude of the oscillation, the differential voltage detected by AGC 110 is reduced. Consequently, the voltage on the contact 214 is reduced to a voltage level lower than the error threshold (when the selector 122 changes the operation mode of the AGC 110 as described in FIG. 8). When the AGC 110 is still in operation by the P-type control path and the voltage of the amplitude of the oscillation is close to the target amplitude of the oscillation, then the voltage of the contact 214 of the AGC has a voltage ripple due to the split mode. However, by selecting the I-type control path in the third region, the voltage ripple is decreased due to the stability of the integral stage 120 of the I-type control path in FIG. 3.

FIG. 10C shows a transient voltage at the output of the integral stage 120 in FIGS. 4A and 4B. The integral stage 120 has twofold phases as described in FIGS. 4A and 4B. In the first and second regions 160 and 170, the integral stage is pre-charged and ready for starting up in the third region 180. The pre-charge phase provides enough voltage level at the output of the integral stage 120 which benefits a fast starting up in the third region 180, when amplitude of the oscillation is close to the target amplitude of the oscillation. In absence of the pre-charge phase, by switching from the P-type control path in the second region 170 into the I-type control path in the third region 180, a discontinuity in the loop operation may result in distortion of the Lissajous pattern of the oscillatory motion of the mass 150 in FIG. 2. In addition, by operating the I-type control path in the third region 180, the contact 214 of the AGC 110 is more stable and the ripple of the split mode is removed from the oscillator output.

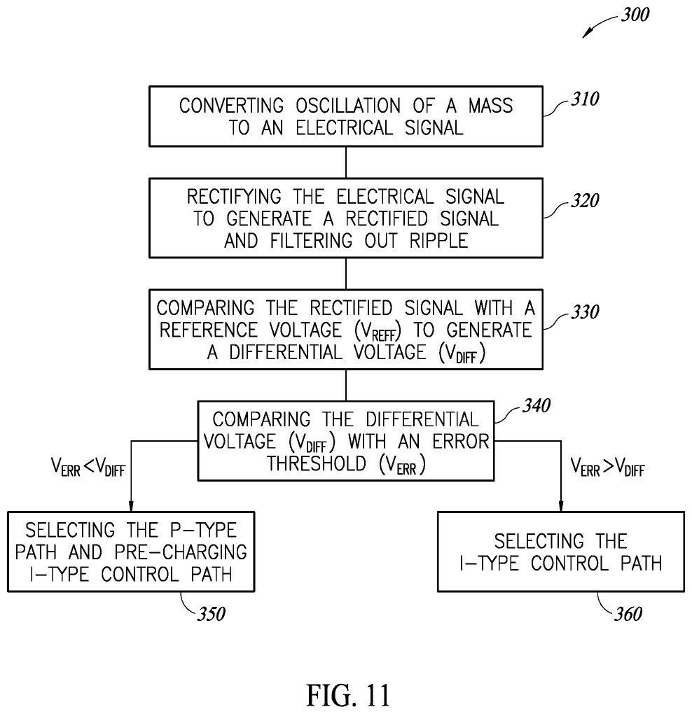

FIG. 11 is a flowchart 300 illustrating a process of the control system described in FIGS. 2 and 3. At block 310, an oscillatory motion of the mass 150 is converted to an electrical signal by the charge amplifier 104 in FIG. 2. An amplitude of the converted signal is proportional to an amplitude of the oscillatory motion. The converted signal is an input of the AGC 110 described in FIG. 3.

At block 320, the converted signal is rectified by the rectifier 112 of the AGC 110 in FIG. 3. The rectifier 112 receives an AC signal proportional to the oscillatory motion and converts it to a rectified DC signal. In some embodiments, the value of the DC signal is proportional to the amplitude of the oscillatory motion. In addition, the low-pass filter 114 is filtering out a frequency ripple of the rectified signal to supply a clean DC signal to the difference amplifier 116.

At block 330, the difference amplifier 116 receives the DC signal from the low-pass filter 114 and compares the DC signal with a reference voltage (V_{reff}) to generate a differential voltage (V_{diff}). The reference voltage is proportional to a target amplitude of the oscillation. Thus, the difference amplifier 116 measures the difference between the current oscillation and a target oscillation and generates the differential voltage (V_{diff}). The differential voltage (V_{diff}) may be the basis of compensation voltage to be derived by the H-bridge 108 to the mass 150, to compensate for the difference between the amplitude of the oscillation and the target amplitude of the oscillation.

At block 340, the selector 122 compares the differential voltage (V_{diff}) with an error threshold (Vₑᵣᵣ). As a result of the comparison, the selector 122 selects the P-type control path if the differential voltage (V_{diff}) is greater than the error threshold (Vₑᵣᵣ). In this condition, at block 350, the AGC 110 is in start-up mode and the P-type control path provides fast start-up response for the oscillation. In addition, the I-type control path is pre-charging during the start-up mode to be ready for fast operation when it is selected by the selector 122.

When the selector 122 detects that the differential voltage (V_{diff}) is less than the error threshold (Vₑᵣᵣ), the selector 122 selects the I-type control path for a slow-mode control of AGC. The I-type control path is pre-charged in the start-up mode and is ready for fast starting up when the I-type control path is selected by the selector 122. The I-type control path may control the oscillation of the oscillator 200 until the MEMS gyroscope 100 stops the operation or an interrupt happens during the oscillatory motion. During the slow mode operation, the I-type control path provides more stable and low noise output to the H-bridge 108, compared with the P-type control path which is suitable for a fast start-up mode.

In some embodiments, the block 340 is repeated during the process of the block 350 and 360. In this fashion, when the V_{diff} is greater than Vₑᵣᵣ and the AGC 110 is operating with the P-type control path, the block 340 is operating to detect if the V_{diff} is still greater than Vₑᵣᵣ. Once, in block 340, the selector 122 detects that the V_{diff} is less than Vₑᵣᵣ, it then selects the I-type control path to switch from the block 350 to the block 360. In a similar fashion, once, in block 340, the selector 122 detects that the V_{diff} is again greater than Vₑᵣᵣ, it then selects the P-type control path to switch back from the block 360 to the block 350.

A system may be summarized as including a gyroscope having a mass; and an oscillator coupled to the mass, the oscillator configured to cause an oscillatory motion of the mass, the oscillator including: a converter coupled to the mass and configured to convert the oscillatory motion to an oscillatory signal; a driver coupled to the mass and configured to cause the oscillatory motion by actuating the mass; and a control loop coupled between the converter and the driver to control the oscillatory motion of the mass, the control loop including: a rectifier configured to rectify the oscillatory signal to generate a rectified signal; a difference amplifier configured to compare the rectified signal to a reference signal, and generate a differential signal based on the comparison; a gain control path configured to control a start of the oscillatory motion of the mass; an integral control path coupled in parallel to the gain control path and configured to control a steady state of the oscillatory motion of the mass; and a selector configured to select the gain control path in response to the differential signal being greater than a threshold value, and select the integral control path in response to the differential signal being less than the threshold value.

The control loop may be an automatic gain control (AGC), and the gain control path may provide a proportional control (P-type) path.

The driver may be an H-bridge driver.

The converter may be a charge amplifier that converts the oscillatory motion to a sinusoidal electrical wave.

The oscillator may further include a phase shifter coupled to the charge amplifier and configured to compensate a phase shift introduced by the charge amplifier into the sinusoidal electrical wave.

The oscillator may further include a hard limiter coupled between the phase shifter and the driver and configured to generate a square-wave from the sinusoidal electrical wave, the square wave is applied to the driver to actuate the mass.

The integral control path may be a switched capacitor circuit.

The integral control may be pre-charged in response to the gain control being selected by the selector.

The selector may select the gain control path in response to the differential signal being greater than a threshold value, and may select the integral control path in response to the differential signal being less than the threshold value.

The gyroscope may be a Lissajous frequency modulated (LFM) gyroscope.

A method may be summarized as including actuating, by an oscillator, a mass of a gyroscope to generate an oscillatory motion of the mass; converting, by the oscillator, the oscillatory motion of the mass to an oscillatory signal; generating, by the oscillator, a rectified signal by rectifying the oscillatory signal; generating, by the oscillator, a differential signal by comparing the rectified signal to a reference voltage; selecting a gain control path in response to the differential signal being greater than a threshold value, the gain control path being configured to control a start of the oscillatory motion of the mass; and selecting an integral control path in response to the differential signal being less than the threshold value, the integral control path being configured to control a steady state of the oscillatory motion of the mass.

The selector selecting the gain control path in response to the differential signal may be greater than a threshold value, and selecting the integral control path in response to the differential signal may be less than the threshold value.

The method may further include pre-charging the integral control path when the gain control path is selected by the selector.

The method may further include adjusting an amplitude of the oscillatory motion by the driver based on the differential signal.

The method may further include filtering the rectified signal by a low-pass filter to remove a frequency ripple caused by the oscillatory signal.

A device may be summarized as including a mass; and an oscillator coupled to the mass, the oscillator configured to cause an oscillatory motion of the mass, the oscillator including: an automatic gain control (AGC) configured to control the oscillatory motion of the mass, the AGC including: a rectifier configured to generate a rectified signal based on the oscillatory motion; a difference amplifier configured to generate a differential signal based on a comparison between the rectified signal and a reference voltage; a first control path; a second control path coupled in parallel to the first control path; and a selector configured to select the first control path in response to the differential signal being greater than a threshold value, and select the second control path in response to the differential signal being less than the threshold value.

The oscillatory motion may be a Lissajous pattern.

The first control path may include a gain stage, and the second control path may include a switched capacitor circuit.

The gain stage may include an inverting op-amp circuit to provide a proportional control (P-type) path, and the switched capacitor circuit may provide an integral control (I-type) path.

The switched capacitor circuit may be pre-charged in response to the gain stage being selected by the selector.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A system, comprising:
a gyroscope having a mass; and
an oscillator coupled to the mass, the oscillator configured to cause an oscillatory motion of the mass, the oscillator including:
a converter coupled to the mass and configured to convert the oscillatory motion to an oscillatory signal;
a driver coupled to the mass and configured to cause the oscillatory motion by actuating the mass; and
a control loop coupled between the converter and the driver to control the oscillatory motion of the mass, the control loop including:
a rectifier configured to rectify the oscillatory signal to generate a rectified signal;
a difference amplifier configured to compare the rectified signal to a reference signal, and generate a differential signal based on the comparison;
a gain control path configured to control a start of the oscillatory motion of the mass;
an integral control path coupled in parallel to the gain control path and configured to control a steady state of the oscillatory motion of the mass; and
a selector configured to select the gain control path in response to the differential signal being greater than a threshold value, and select the integral control path in response to the differential signal being less than the threshold value.

2. The system of claim 1, wherein the control loop is an automatic gain control, and the gain control path provides a proportional control path.

3. The system of claim 1, wherein the driver is an H-bridge driver.

4. The system of claim 1, wherein the converter is a charge amplifier that converts the oscillatory motion to a sinusoidal electrical wave.

5. The system of claim 4, wherein the oscillator further includes a phase shifter coupled to the charge amplifier and configured to compensate a phase shift introduced by the charge amplifier into the sinusoidal electrical wave.

6. The system of claim 5, wherein the oscillator further includes a hard limiter coupled between the phase shifter and the driver and configured to generate a square-wave from the sinusoidal electrical wave, the square wave is applied to the driver to actuate the mass.

7. The system of claim 1, wherein the integral control path is a switched capacitor circuit.

8. The system of claim 7, wherein the integral control is pre-charged in response to the gain control being selected by the selector.

9. The system of claim 8, wherein the selector selects the gain control path in response to the differential signal being greater than a threshold value, and selects the integral control path in response to the differential signal being less than the threshold value.

10. The system of claim 1, wherein the gyroscope is a Lissajous frequency modulated gyroscope.

11. A method, comprising:
actuating, by an oscillator, a mass of a gyroscope to generate an oscillatory motion of the mass;
converting, by the oscillator, the oscillatory motion of the mass to an oscillatory signal;
generating, by the oscillator, a rectified signal by rectifying the oscillatory signal;
generating, by the oscillator, a differential signal by comparing the rectified signal to a reference voltage;
selecting a gain control path in response to the differential signal being greater than a threshold value, the gain control path being configured to control a start of the oscillatory motion of the mass; and
selecting an integral control path in response to the differential signal being less than the threshold value, the integral control path being configured to control a steady state of the oscillatory motion of the mass.

12. The method of claim 11, wherein a selector selecting the gain control path in response to the differential signal is greater than a threshold value, and selecting the integral control path in response to the differential signal is less than the threshold value.

13. The method of claim 11, further comprising:
pre-charging the integral control path when the gain control path is selected by a selector.

14. The method of claim 11, further comprising:
adjusting an amplitude of the oscillatory motion by a driver based on the differential signal.

15. The method of claim 11, further comprising:
filtering the rectified signal by a low-pass filter to remove a frequency ripple causing by the oscillatory signal.

16. A device, comprising:
a mass; and
an oscillator coupled to the mass, the oscillator configured to cause an oscillatory motion of the mass, the oscillator including:
an automatic gain control configured to control the oscillatory motion of the mass, the automatic gain control including:
a rectifier configured to generate a rectified signal based on the oscillatory motion;
a difference amplifier configured to generate a differential signal based on a comparison between the rectified signal and a reference voltage;
a first control path;
a second control path coupled in parallel to the first control path; and
a selector configured to select the first control path in response to the differential signal being greater than a threshold value, and select the second control path in response to the differential signal being less than the threshold value.

17. The device of claim 16, wherein the oscillatory motion is a Lissajous pattern.

18. The device of claim 16, wherein the first control path includes a gain stage, and the second control path includes a switched capacitor circuit.

19. The device of claim 18, wherein the gain stage includes an inverting op-amp circuit to provide a proportional control path, and the switched capacitor circuit provides an integral control path.

20. The device of claim 18, wherein the switched capacitor circuit is pre-charged in response to the gain stage being selected by the selector.
